(19) United States
(12) Patent Application Publication
(10) Pub. No.: US 2014/0333936 A1
(43) Pub. Date: Nov. 13, 2014

(54) THICKNESS MEASURING SYSTEM AND METHOD FOR A BONDING LAYER

(71) Applicant: INDUSTRIAL TECHNOLOGY RESEARCH INSTITUTE, Hsinchu (TW)

(72) Inventors: Po-Yi CHANG, Taichung City (TW); Chia-Hung CHO, Hsinchu City (TW); Yi-Sha KU, Hsinchu City (TW); Deh-Ming SHYU, Zhubei City (TW)

(73) Assignee: INDUSTRIAL TECHNOLOGY RESEARCH INSTITUTE, Hsinchu (TW)

(21) Appl. No.: 14/270,962

(22) Filed: May 6, 2014

Related U.S. Application Data
(60) Provisional application No. 61/821,805, filed on May 10, 2013.

(30) Foreign Application Priority Data
Jan. 2, 2014 (TW) 103100063

(51) Int. Cl. G01B 11/06; H01L 21/66

(52) U.S. Cl. CPC G01B 11/06; H01L 22/26
USPC 356/503

(57) ABSTRACT

In a thickness measuring system for a bonding layer according to an exemplary embodiment, an optical element changes the wavelength of a first light source to enable at least one second light source propagating through a bonding layer to be incident to an object, wherein the bonding layer has an upper interface and a lower interface that are attached to the object; and an optical image capturing and analysis unit receives a plurality of reflected lights from the upper and the lower interfaces to capture a plurality of interference images of different wavelengths, and analyzes the intensity of the plurality of interference images to compute the thickness information of the bonding layer.

### CROSS-REFERENCE TO RELATED APPLICATION

The present application is based on, and claims priorities from, U.S. Provisional Application No. 61/821,805, filed May 10, 2013, and Taiwan Patent Application No. 103100063, filed Jan. 2, 2014, the disclosure of which is hereby incorporated by reference herein in its entirety.

### TECHNICAL FIELD

The technical field generally relates to a thickness measuring system and method for a bonding layer.

### BACKGROUND

Wafer thinning and thin wafer handling technology is one of the important three-dimensional integrated circuits (3DIC) stacking technologies. The device wafer to be thinned is bonded temporarily to a carrier wafer may avoid damage risk caused by the gravity and other factors after thinning and backside processing of a wafer. Voids and particles on the interface of the carrier wafer, adhesive layer thickness, and adhesive gum dent may all affect thickness uniformity of a thin wafer. Therefore, inspecting these defects before wafers thinning is one way to be done.

The scanning acoustic microscope (SAM) and the infrared ray (IR) transmission imaging techniques are usually used in inspecting voids and particles on the adhesive interface layer of the temporarily bonded wafer. For example, the use of an ultrasound technology to measure a 12-inch wafer may take measurement time of around 10 minutes, and measurement spatial resolution of about 50 μm, with the wafer immersed in liquid. Some existing technologies do not need the wafer to be immersed in liquid, but need to spray liquid between the inspection probe and the wafer. The infrared ray transmission image technology is a full-field inspection technique to detect larger bubbles inside the bonding layer. Tiny bubbles are coupled with other algorithms to enhance showing defects. These two techniques may detect the voids of the bonding layer, but may not measure thickness information of the bonding layer, such as thickness variation, total thickness, absolute thickness, etc.

Infrared ray wavelength scanning interferometry is one method used to measure the thickness of the silicon wafer. For example, the phase-shifting technology, the Fourier transform based method and the zero-crossing detection method are commonly used to analyze interference signals. In the Fourier transform based method, the minimum measurable thickness and its thickness sensitivity are limited to a wavelength tuning range. The phase-shifting technology is capable of measuring the thickness variation of the wafer. The zero-crossing detection method may be used to measure the surface shape of the wafer in real-time.

In measuring the wafer thickness with the infrared ray wavelength scanning interferometer, when an object is a wafer of double-sides polished, the reflected light is generated by the infrared light on the front surface and the back surface of the wafer. Due to path of the reflected light propagating through the wafer is shortened, the reflected light may produce the Doppler shift, resulting in a slight change of frequency which may be used to measure the thickness variation of the wafer.

In measuring the wafer thickness with the infrared Michelson interferometer, including such as a scheme of using broadband light sources and changing optical path difference, this scheme is capturing continuous interference images, and using analysis of interference envelope to calculate the wafer thickness. It may also use the infrared reflectometry-based Michelson interferometer to measure the wafer thickness and the wafer surface shape, wherein the Michelson interferometer may obtain the three reflected lights of the wafer front surface, the wafer back surface, and the reference plane. These three lights interference each other, and its interference fringes can be analyzed by using a spectrometer or a wavelength scanning scheme to obtain the interference frequency spectrum, and then analyzing the wafer thickness and the wafer surface shape.

### SUMMARY

Exemplary embodiments of the present disclosure may provide a thickness measuring system and method for a bonding layer.

One of exemplary embodiments relates to a thickness measuring system for a bonding layer. The thickness measuring system may comprise an optical element and an optical image capturing and analyzing unit. The optical element changes a wavelength of a first light source to enable at least one second light source propagating through a bonding layer to be incident to an object, wherein the bounding layer has an upper interface and a lower interface that are attached to the object. The optical image capturing and analyzing unit receives a plurality of reflected lights from the upper and the lower interfaces to capture a plurality of interference images of different wavelengths, and analyzes at least one light intensity of the plurality of interference images to compute a thickness information of the bonding layer.

Another exemplary embodiment relates to a thickness measuring method for a bonding layer. The thickness measuring method may comprise: changing a wavelength of a first light source to enable at least one second light source propagating through a bonding layer to be incident to an object, wherein the bounding layer has an upper interface and a lower interface that are attached to the object; receiving a plurality of reflected lights from the upper and the lower interfaces of the bonding layer; and analyzing at least one light interference intensity of the plurality of reflected lights to compute a thickness information of the bonding layer.

The foregoing and other features and aspects of the disclosure will become better understood from a careful reading of a detailed description provided herein below with appropriate reference to the accompanying drawings.

### BRIEF DESCRIPTION OF THE DRAWINGS

FIG. 1 shows a thickness measuring system for a bonding layer, according to an exemplary embodiment.

FIG. 2 shows a thickness measuring method for a bonding layer, according to an exemplary embodiment.

FIG. 3 shows a schematic view illustrating an application exemplar, according to an exemplary embodiment.

FIG. 4 shows how to calculate thickness information of a bonding layer, according to an exemplary embodiment.

FIG. 5 shows a schematic view illustrating the relationship between light interference intensity of the reflected light from the upper and the lower interfaces of the bonding layer and the layer thickness for the application exemplar of temporarily bonded wafer in FIG. 3.

FIG. 6 shows how to calculate the thickness at a single point of the bonding layer, according to an exemplary embodiment.

FIG. 7 shows the curve fitting of the interference signals simulated according to light interference theory and the interference spectrum curve of a single point in a plurality of interference images, according to an exemplary embodiment.

FIG. 8 shows phase-shifting and wavelength of five interference images by using a five-step phase-shifting method, according to an exemplary embodiment.

FIG. 9 shows measurement results of the thickness variation of a bonding layer, according to an exemplary embodiment.

### DETAILED DESCRIPTION OF DISCLOSED EMBODIMENTS

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

Exemplary embodiments in the disclosure may provide a thickness measurement technology of a bonding layer. The bonding layer is, for example, but not limited to, a temporary bonding interface (such as an adhesive layer) of a wafer. Take an object is a wafer as an example, the bonding layer is such as a temporary bonding interface of the wafer, the bonding layer has an upper interface and a lower interface, and the upper and the lower interface are bonded to the wafer. This technique may use an optical element such as interferometer, phase-shift based theory, and reflection theory to measure the thickness information of the adhesive interface layer, such as the thickness of the adhesive interface layer and the thickness variation of the adhesive interface layer, to establish the thickness distribution map of the temporary bonding adhesive interface layer of the wafer through the single-point thickness of the adhesive interface layer and the thickness variation of the adhesive interface layer.

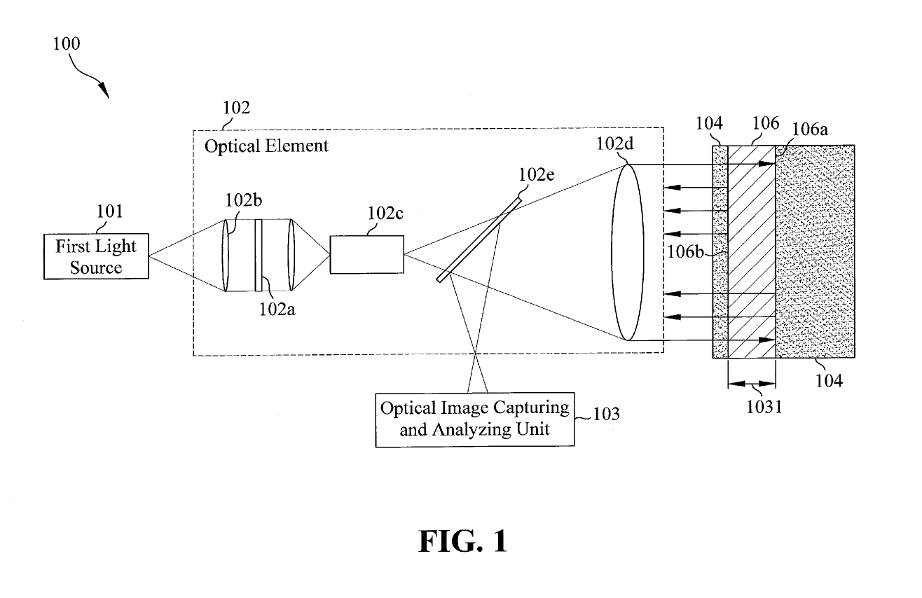

FIG. 1 shows a thickness measuring system for a bonding layer, according to an exemplary embodiment. Referring to FIG. 1 , a thickness measurement system 100 comprises an optical element 102 and an optical image capturing and analyzing unit 103. The optical element 102 changes the wavelength of a first light source 101 to enable at least one second light source (represented by an arrow →) propagating through a bonding layer 106 to be incident to an object 104, wherein the bounding layer 106 has an upper interface 106a and a lower interface 106b, and these two interfaces (106a and 106b) are attached to the object 104. The light image capturing and analyzing unit 103 receives a plurality of reflected lights 1061 reflected from the upper and the lower interfaces to capture a plurality of interference images of different wavelengths, and analyzes light intensities of the plurality of interference images to compute thickness information 1031 of the bonding layer 106.

According to the exemplary embodiments of the disclosure, the object may be such as a wafer. The bonding layer may be an adhesive interface layer bonded to the wafer. In the optical element, it may rotate different angles of an interference filter. For example, along an optical axis, it may begin from 10° with every increment of 0.25° to up to 45° to adjust different wavelengths of the first light source 101 propagating through the interference filter. For example, the optical element may use an optical collimator 102b to make the first light source 101 to be incident to an interference filter 102a, then the at least one second light source may propagate through the bonding layer 106 to be incident to this object through such as a light source beam expander 102c and a lens 102d. The plurality of interference images captured by the optical image capturing and analyzing unit is a plurality of generated light interference intensity images reflected by a beam splitter 102e after the at least one second light source is incident (represented by an arrow →) to the upper and the lower interfaces of the bonding layer to cause mutual interference through one or more reflected lights (represented by an arrow ←) of the upper and the lower interfaces. The thickness information of the bonding layer at least may include the absolute thickness data of at least one single point of the bonding layer and full-field thickness distribution information of the bonding layer. With the absolute thickness data of the at least one single point of the bonding layer and full-field thickness distribution information of the bonding layer, the thickness measuring system 100 may further perform an analysis to obtain information related to the object, such as using a curve fitting method to generate information of the surface shape of the object.

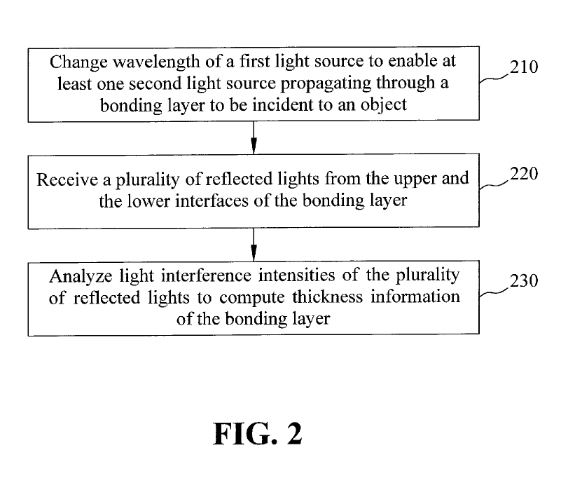

According to an exemplary embodiment of the disclosure, a thickness measuring method for a bonding layer is provided as shown in FIG. 2. Referring to FIG. 2, the thickness measuring method may change wavelength of a first light source to enable at least one second light source propagating through a bonding layer to be incident to an object (step 210). As mentioned above, the bounding layer has an upper interface and a lower interface that are attached to the object. Then the thickness measuring method may receive a plurality of reflected lights from the upper and the lower interfaces of the bonding layer (step 220), and may analyze light interference intensities of the plurality of reflected lights to compute thickness information of the bonding layer (step 230).

According to the disclosed embodiment, the thickness measurement method may use different rotation angles of an interference filter to change wavelength of the first light source, to generate the at least one second light source. The following takes a temporary bonded wafer as an application exemplar to illustrate the thickness measuring technology of the disclosure. In the application exemplar, the first light source is a tunable wavelength light source; the temporarily bonded wafer includes an object such as a wafer, and a bonding layer, wherein the bonding layer such as a layer has an upper interface and a lower interface.

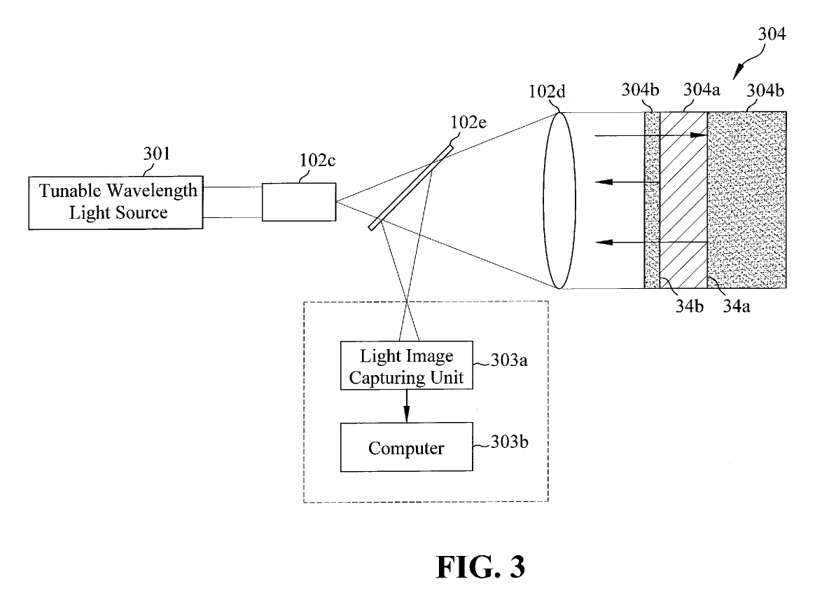

FIG. 3 shows a schematic view illustrating an application exemplar, according to an exemplary embodiment. In the application exemplar, after the tunable wavelength light source 301 has been beam expanded and collimated through the light beam expander lens 102c and 102d of the optical element 102, the tunable light source 301 is incident (represented by an arrow →) to a temporarily bonded wafer 304. This temporarily bonded wafer includes an adhesive layer 304a temporarily bonded to a wafer 304b. The reflected lights (indicated by arrows ←) of the upper and the lower interfaces (34a and 34b) of a layer 304a bonded to a surface of the temporarily bonded wafer 304 interfere with each other. Thus the optical image capturing and analyzing unit, such as a light image capturing unit 303a captures light interference intensities of the reflected waves, and a thickness analysis unit such as a computer 303b, a computing device, a processor etc. analyze data of the light interference intensities to calculate the thickness information of the adhesive layer 304a.

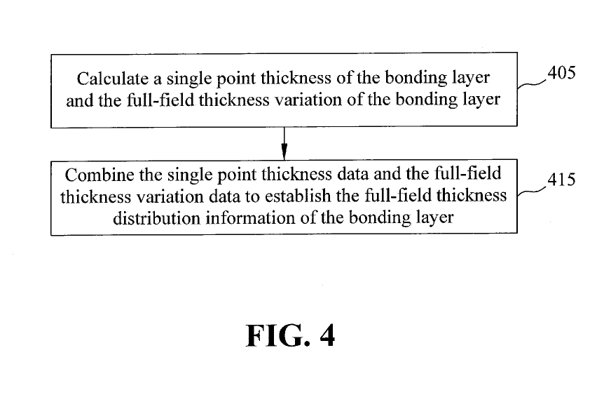

According to an exemplary embodiment of the disclosure, as shown in FIG. 4, the calculation of thickness information of a bonding layer may include: calculating a single point thickness of the bonding layer and the full-field thickness variation of the bonding layer (step 405); and combining the single point thickness data and the full-field thickness variation data to establish the full-field thickness distribution information of the bonding layer (step 415).

According to the exemplary embodiment, the thickness measurement may calculate the thickness based on the light interference theory (such as infrared light wavelength scanning interferometry technology), the phase-shifting technology, and coupled with the spectrum curve fitting technique. Using the light interference theory, the relationship between the light interference intensity of a plurality of interference images captured by the optical image capturing and analyzing unit and the bonding layer thickness may be expressed as follows:

I(k;x,y)=I₀(x,y)+A(x,y)cos {2kn·L(x,y)}, (1)

wherein L(x, y) is the thickness of the bonding layer corresponding to a pixel (x, y) of the bonding layer;
I(k; x, y) is the light interference intensity of the reflected wave on the pixel (x, y) of the bonding layer;
I₀(x,y) is the light interference intensity on the pixel (x,y) of the interference image background;
A(x,y) is the interference light amplitude on the pixels (x,y), in unit of micron;
n is the refractive index of the bonding layer; and
λ is the wavelength of the reflected light wave, in units of nano meter (nm).

The absolute thickness of the bonding layer corresponding to a pixel (x,y) is L(x,y)=ΔL+h(x,y), wherein ΔL is the average thickness of the bonding layer; h(x,y) is the thickness variation on the pixel (x, y) of the bonding layer; and k=2π/λ. Therefore, in the formula (I), the light interference intensity on a single point (x,y) of the bonding layer surface may be expressed as follows:

I(k;x,y)=I₀(x,y)+A(x,y)cos {2kn·[L(x,y)+h(x,y)]} (2)

According to different wavelengths λ, the light interference intensity on the single point (x,y) may be expressed as follows:

I(λ,x,y)=I₀(x,y)+A(x,y)cos {4πn·L(x,y)·1/λ} (3)

And its corresponding specific phase φ(x,y) may be expressed as

φ(x,y)=2kn·[L(x,y)+h(x,y)] (4)

As previously described, the reflective lights of the upper and the lower interfaces of the bonding layer will interfere with each other, the phase variation of the two-wavelength interferometer may be expressed as follows:

$$Δφ = \frac{2 π}{λ} \cdot n \cdot 2 [ Δ L + h ( x , y ) ] - \frac{2 π}{λ + Δλ} \cdot n \cdot 2 [ Δ L + h ( x , y ) ] \qquad ( 5 )$$

wherein Δλ is the wavelength variation.

### That is

$$\begin{matrix}Δφ = \frac{2 π}{λ} \cdot n \cdot 2 [ Δ L + h ( x , y ) ] \cdot \frac{λ}{λ ( λ + Δλ )} & ( 6 ) \\ Δφ = 4 π n Δ L \frac{Δλ}{{λ}^{2}} & ( 7 ) \\ Δ L ≫ h ( x , y ) , Δλ ≪ λ & ( 8 )\end{matrix}$$

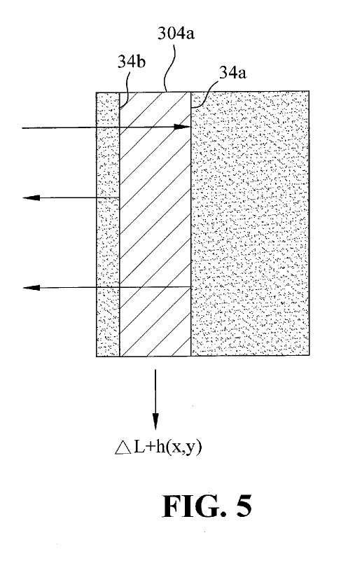

Takes the temporarily bonded wafer of FIG. 3 as an application exemplar, according to the above formula, FIG. 5 shows the relationship between light interface intensities of the reflected lights from the upper and the lower interfaces (34a and 34b) of the adhesive layer 304a and the thickness of the adhesive layer 304a. The corresponding absolute thickness at the pixel (x,y) on the surface of the adhesive layer 304a is the average thickness ΔL of the adhesive layer 304a added with the thickness variation h(x,y) at the pixel (x,y) of the adhesive layer 304a. The thickness variation h(x,y) may derive the following formula:

h(x,y)=(φ/4πn)·λ

wherein λ is the wavelength of the reflected wave, n is the reflectance index of the adhesive layer 304a, φ is the corresponding phase of the light interference intensity of the reflected light wave at the pixel (x,y).

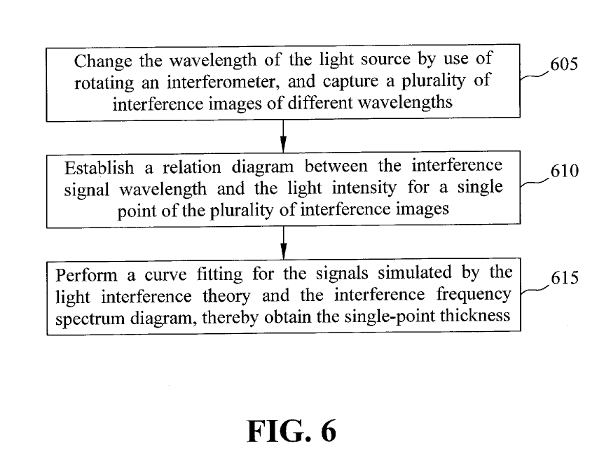

Accordingly, FIG. 6 shows how to calculate the thickness at a single point of the bonding layer, according to an exemplary embodiment. Referring to FIG. 6, the calculation method firstly changes the wavelength of the light source by use of rotating an interferometer, and captures a plurality of interference images of different wavelengths (step 605), then establishes a relation diagram (i.e., the interference frequency spectrum diagram) between the interference signal wavelength and the light intensity for the single point of the plurality of interference images (step 610), then performs a curve fitting for the signals simulated by the light interference theory and the interference frequency spectrum diagram, thereby obtains the single-point thickness (step 615).

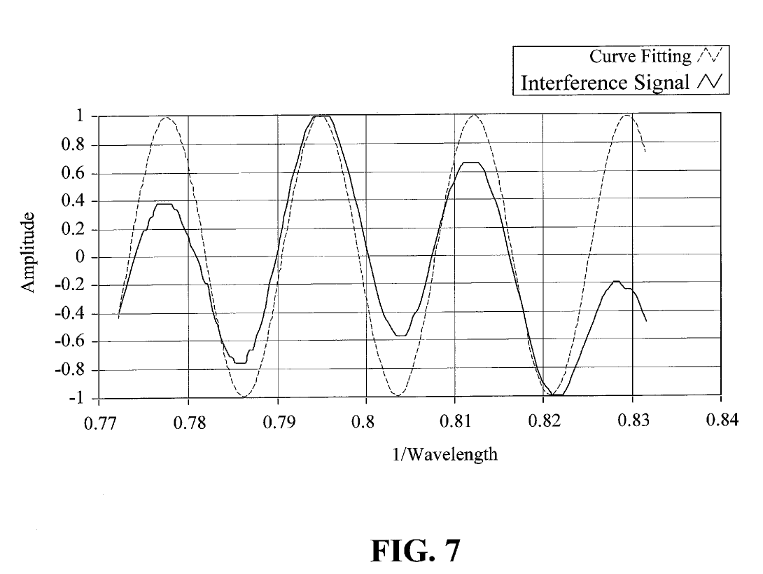

FIG. 7 shows the curve fitting of the interference signals simulated according to light interference theory and the interference spectrum curve of a single point in a plurality of interference images, according to an exemplary embodiment, wherein a solid line curve represents interference signals simulated by the light interference theory, a dotted line curve represents the curve fitting made by using interference frequency spectrum diagram on the single point in the plurality of interference images, the horizontal axis represents 1/λ, i.e., 1/wavelength, the vertical axis represents amplitude. The frequency spectrum curve fitting made from the interference frequency spectrum diagram may preliminarily decide the average thickness ΔL of the bonding layer. The single-point thickness may be set to the average thickness ΔL decided from the frequency spectrum curve fitting.

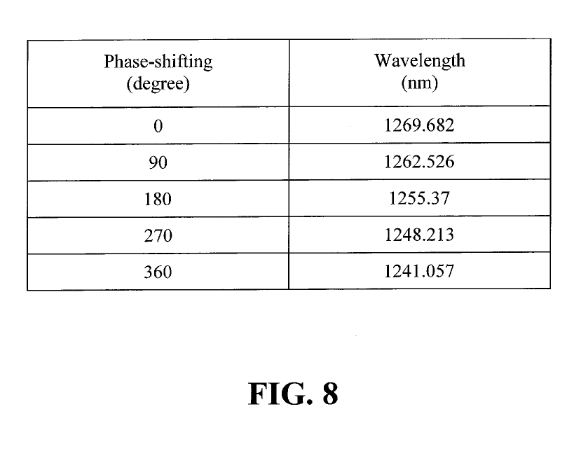

After obtaining a single-point thickness, the interference image of a specific phase may be selected from a plurality of interference phase diagrams by changing the amount of the wavelength (i.e., Δλ), and the phase of each pixel (x,y) is calculated by using a phase algorithm such as tree-step, four-step, or five-step phase-shifting method and a phase expansion method. As shown in the exemplary embodiment of FIG. 8, the five-step phase-shifting method of taking five reference phase-shiftings, i.e. Δφ=(i−1)×π/2 and i=1, 2, 3, 4, 5, is used to capture the interference images of five different wavelengths, then the light intensities I₁˜I₅ of each pixel (x,y) of five interference images may be expressed respectively as follows:

I₁=I₀(x,y)+A(x,y)cos [wt+φ(x,y)]

I₂=I₀(x,y)+A(x,y)cos [wt+φ(x,y)+π/2]

I₃=I₀(x,y)+A(x,y)cos [wt+φ(x,y)+π]

I₄=I₀(x,y)+A(x,y)cos [wt+φ(x,y)+π/2]

I₄=I₀(x,y)+A(x,y)cos [wt+φ(x,y)+2π]

Therefore, the specific phase φ(x,y) corresponding to the pixel (x,y) may be expressed as

$$φ ( x , y ) = {tan}^{- 1} [ \frac{2 ( {I}_{2} - {I}_{4} )}{- {I}_{1} + 2 {I}_{3} - {I}_{5}} ] \qquad ( 10 )$$

That is, the specific phase φ(x, y) may be calculated by the light intensities I₁˜I₅ of each pixel (x,y) of the said five interference images. Then, the thickness variation h (x,y) of the full-field bonding layer may be derived by using the equation h(x, y)=(φ/4πn)·λ. Therefore, thickness variation of the full-field bonding layer may be calculated according to the phase value.

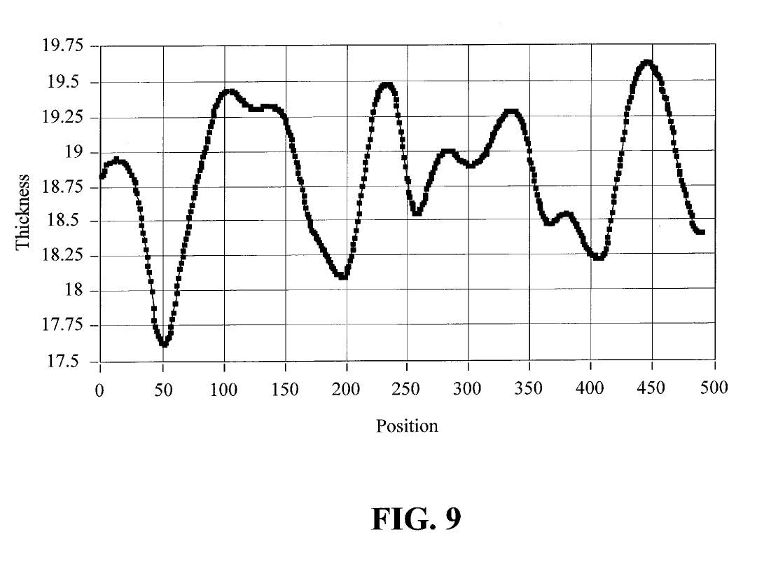

In other words, calculating the full-field thickness variation of a bonding layer may comprise: selecting a plurality of interference images of several specific phases in a plurality of interference phase diagrams by changing an amount of the wavelength of the first light source; and using a phase-shifting method to calculate a corresponding phase of each pixel (x,y) of the bonding layer, then calculating full-field thickness variation of the bonding layer based on each calculated phase; finally integrating the data of the single-point thickness and the data of full-field thickness variation information of the bonding layer to establish the thickness distribution of the full-field bonding layer. FIG. 9 shows measurement results of the thickness variation of a bonding layer, according to an exemplary embodiment. Wherein the horizontal axis represents the pixel position of the bonding layer, and the vertical axis represents the thickness of the bonding layer (in units of micrometers (μm)). In the experimental exemplar of FIG. 9, the maximum thickness 19.86 μm of the bonding layer is approximately located at the position 450, the minimum thickness 16.09 μm of the bonding layer is approximately located at the position 50 according to the curve distribution results. That is, the thickness of the bonding layer may vary from 16.09 μm to 19.86 μm. In other words, the total thickness variation of the bonding layer is 3.76 μm, i.e., the difference between the maximum thickness and the minimum thicknesses.

In summary, the exemplary embodiment of the present disclosure provides a thickness measuring system and method for a bonding layer. This technique may use such as interferometer, phase-shifting based theory and reflection theory, and frequency spectrum curve fitting to analyze the light intensity of a plurality of interference images and the thickness information of measuring the bonding layer. The thickness information is such as, but not limited to the single-point thickness and the full-field thickness variation of the bonding layer. The thickness distribution of a bonding layer of an object may also be established by the single-point thickness of the bonding layer and the thickness variation of the bonding layer.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A thickness measuring system for a bonding layer, comprising:
an optical element that changes a wavelength of a first light source to enable at least one second light source propagating through the bonding layer to be incident to an object, wherein the bounding layer has an upper interface and a lower interface that are attached to the object; and
an optical image capturing and analyzing unit that receives a plurality of reflected lights from the upper and the lower interfaces to capture a plurality of interference images of different wavelengths, and analyzes at least one light intensity of the plurality of interference images to compute a thickness information of the bonding layer.

2. The system as claimed in claim 1, wherein the object is a wafer.

3. The system as claimed in claim 1, wherein the bonding layer is an adhesive interface layer bonded to the object.

4. The system as claimed in claim 1, wherein the optical element rotates a plurality of different angles of an interference filter to adjust a plurality of different wavelengths of the first light source propagating through the interference filter.

5. The system as claimed in claim 4, wherein the optical element uses an optical collimator to make the first light source to be incident to the interference filter, and the at least one second light source propagates through the bonding layer to be incident to the object through a light source beam expander.

6. The system as claimed in claim 1, wherein the plurality of interference images are a plurality of light interference intensity images, and the plurality of light interference intensity images are generated via a mutual interference of the plurality of reflected lights after the at least one second light source is incident to the upper and the lower interfaces.

7. The system as claimed in claim 1, wherein the thickness information of the bonding layer at least include at least one absolute thickness data of at least one single point of the bonding layer and a full-field thickness distribution information of the bonding layer.

8. The system as claimed in claim 1, wherein the system uses the thickness information of the bonding layer to generate at least one information of a surface shape of the object.

9. A thickness measuring method for a bonding layer, comprising:
changing a wavelength of a first light source to enable at least one second light source propagating through the bonding layer to be incident to an object, wherein the bounding layer has an upper interface and a lower interface that are attached to the object;
receiving a plurality of reflected lights from the upper and the lower interfaces of the bonding layer; and
analyzing at least one light interference intensity of the plurality of reflected lights to compute a thickness information of the bonding layer.

10. The method as claimed in claim 9, wherein computing the thickness information of the bonding layer further includes:
calculating a single-point thickness of the bonding layer and a full-field thickness variation of the bonding layer; and
combining at least one data of the single point thickness and at least one data of the full-field thickness variation to establish a full-field thickness distribution information of the bonding layer.

11. The method as claimed in claim 9, wherein the method uses a plurality of different rotation angles of an interference filter to change the wavelength of the first light source, to generate the at least one second light source.

12. The method as claimed in claim 10, wherein calculating the single-point thickness of the bonding layer further includes:
changing the wavelength of the light source by use of rotating an interferometer, and capturing a plurality of interference images of a plurality of different wavelengths;
establishing an interference frequency spectrum diagram between an interference signal wavelength and light intensity for a single point of the plurality of interference images; and
performing a curve fitting for a plurality of signals simulated by a light interference theory and the interference frequency spectrum diagram, thereby obtaining the single-point thickness.

13. The method as claimed in claim 10, wherein calculating the full-field thickness variation of the bonding layer further includes:
selecting a plurality of interference images of several specific phases in a plurality of interference phase diagrams by changing an amount of the wavelength of the first light source; and
using a phase-shifting method to calculate a corresponding phase of each pixel of the bonding layer, then calculating the full-field thickness variation of the bonding layer based on each calculated phase.

14. The method as claimed in claim 13, wherein the several specific phases are calculated by a plurality of light intensities of each pixel of the plurality of interference images.

15. The method as claimed in claim 12, wherein an average thickness of the bonding layer is preliminarily decided by a frequency spectrum curve fitting made from the interference frequency spectrum diagram.

16. The method as claimed in claim 15, wherein the single-point thickness is set to the average thickness decided from the frequency spectrum curve fitting.
